(19) United States
(12) Patent Application Publication
(10) Pub. No.: US 2002/0070348 A1
(43) Pub. Date: Jun. 13, 2002

(54) Shutter for a UV sensor

(76) Inventors: Richard N. Metzger, Pasadena, CA (US); Thomas M. Veloz, Canyon County, CA (US)

Correspondence Address: DAVID J. MEYER, ESQ., MANATT, PHELPS & PHILLIPS, LLP, 11355 West Olympic Boulevard, Los Angeles, CA, 90064, US

(21) Appl. No.: 09/736,486

(22) Filed: Dec. 13, 2000

(51) Int. Cl. G01N 23/00; H01J 37/20

(52) U.S. Cl. 250/455.11

(57) ABSTRACT

A device for selectively exposing a sensor to ultraviolet (UV) radiation. The device is usable in a heating, ventilation and air conditioning system (HVAC) which includes UV radiation as a method of disinfection. In one embodiment, the device allows for the discontinuous exposure of a UV photodetector to UV radiation, as for example, by a shutter mechanism. In a second embodiment, the UV photdetector itself is manipulated through various electromechanical mechanisms to allow for the selective exposure.

This application relates to sensors for detecting ultraviolet radiation. More particularly, this invention relates to a device for controlling the exposure of sensors for ultraviolet radiation (“UV”) when detection of UV is unnecessary. In preferred embodiments, this invention is specifically implemented to control the exposure of a photodetector to a UV emitting source in a device for disinfection of HVAC equipment, and is referred to as a shutter for a UV sensor.

### BACKGROUND OF THE INVENTION

UV sensing devices are utilized in many applications in industry. However, the performance of such devices when operating in environments where they are exposed to intense UV radiation is plagued by the progressive deterioration of the sensor to the wavelengths they are intended to measure. The response of common photodetectors degrades significantly with exposure to UV radiation, resulting in rapid loss of calibration in such devices. Accordingly, UV sensors must be recalibrated frequently, and have correspondingly short operational life cycles. Complex detector designs and acceptance of low accuracy and performance within the industry have resulted A further result is increased cost and decreased performance in many applications involving treatment of fluid, including both gases and liquids.

One increasingly important application for UV is in disinfection, especially of heating, ventilation and air conditioning systems (“HVAC”). For example commonly assigned U.S. provisional application serial No. 60/154,146 refers to an appliance for disinfection of HVAC systems that employs UV radiation as a disinfection agent. The source of UV in such devices is typically one or more low pressure mercury vapor lamps generally referred to as “germicidal lamps.” In such applications it is important to be able to monitor the level of UV radiation produced by germicidal lamps in order to know when germicidal lamps require replacement. Disinfection will not occur if the UV light irradiating an air stream and/or filters interposed in the air stream is not sufficiently intense to kill disease-causing microorganisms.

It is preferable to monitor the UV output of mercury vapor lamps indirectly, as UV is harmful to the eyes and skin. Accordingly, measurement of UV using instrumentation is desirable. However, as mentioned, if a UV detector is continuously exposed to UV light, its sensitivity decreases, resulting in measurements that are not reliable.

Accordingly, it is an object of this invention to provide a sensor with a UV light shutter to provide stable measurements of UV output, and longer within-calibration lifetime of a UV sensor.

It is a further object of this invention to provide a stable UV detector for incorporation in a UV disinfection system

### SUMMARY OF THE INVENTION

In its broadest terms, the invention disclosed herein provides a source of UV radiation, and a sensor therefore, with a mechanism for preventing UV light from impinging upon the sensor. In preferred embodiments the mechanism is an electromechanically controlled shutter that is interposed between a source of UV and a sensor, allowing for periodic sampling of the UV intensity in the system with appropriate monitoring circuitry.

### BRIEF DESCRIPTION OF THE FIGURES

FIG. 1(a) is a perspective view of exterior surface of a germicidal lamp enclosure including a shutter for a UV sensor according to the invention.

FIG. 1(b) shows the underside of the surface shown in FIG. 1(a) in which shutter (5) covers an opening in the wall of enclosure (2)

FIG. 2(a) depicts the same view as FIG. 1(a), but with the shutter moved away from the first position to expose the photodector to UV radiation.

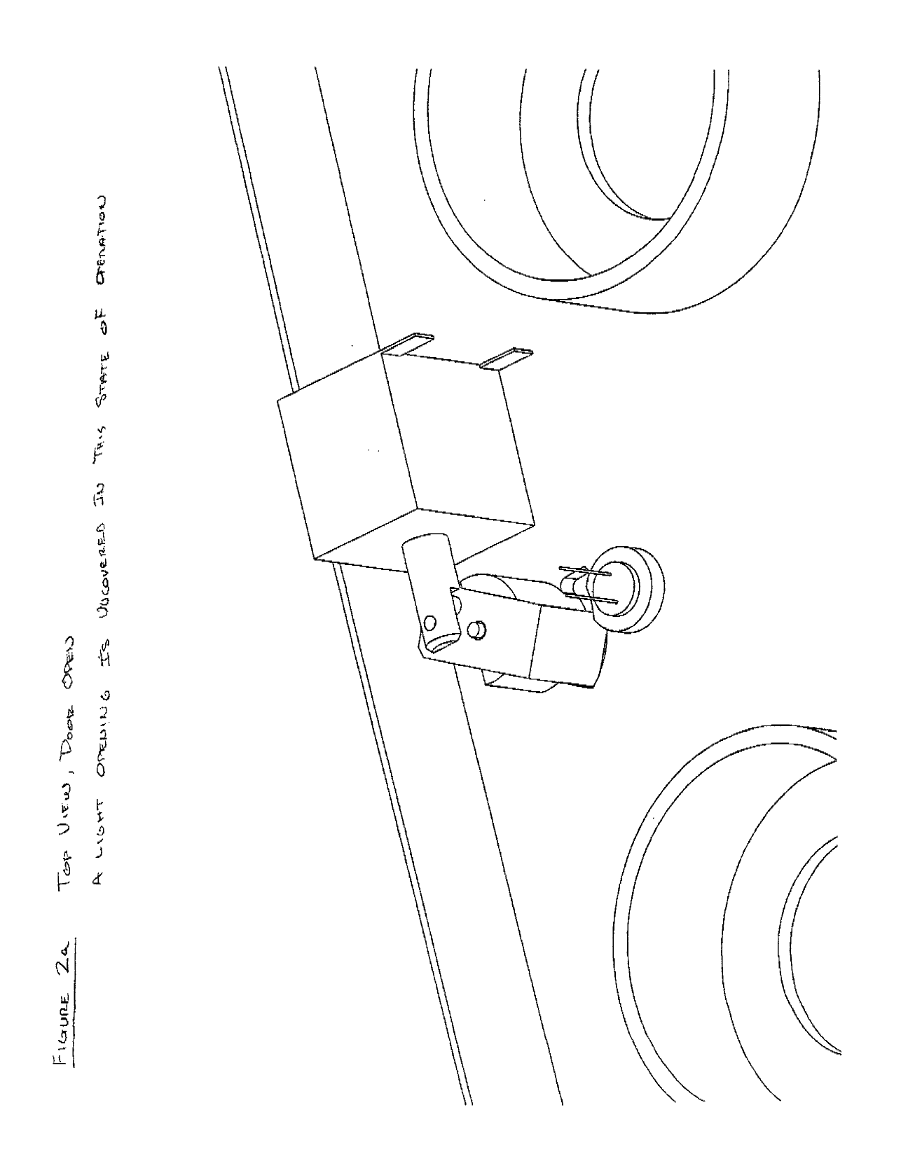

FIG. 2(b) depicts the same view as FIG. 1(b), with the shutter moved away from the first position to expose the photodetector to UV radiation.

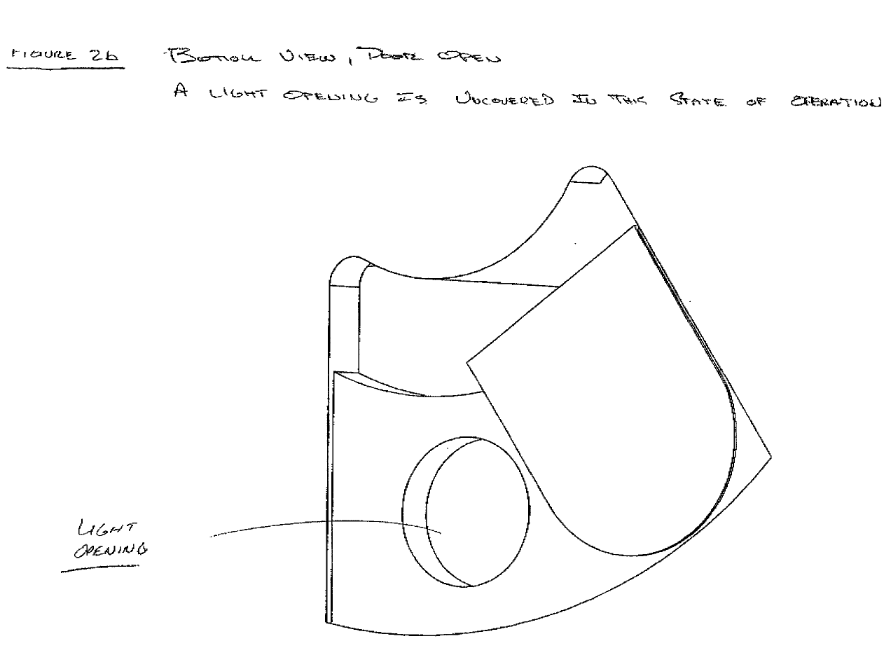

### DETAILED DESCRIPTION

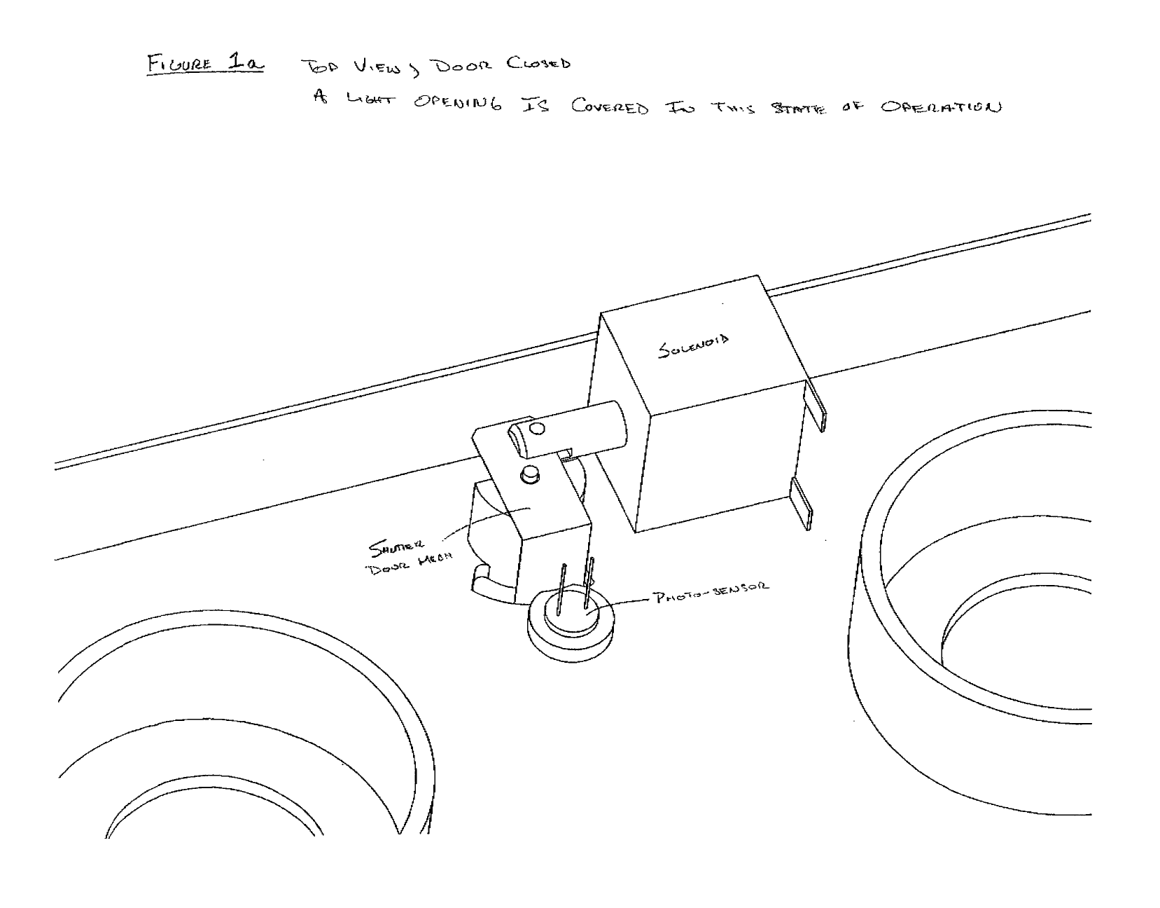

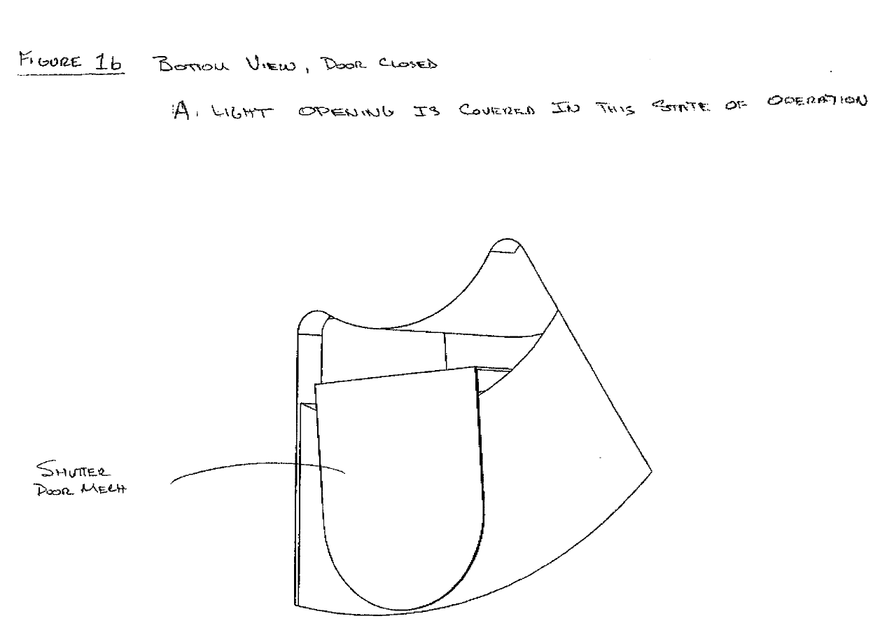

The embodiment depicted in FIG. 1 shows a solenoid controlling the position of a shutter functionally mounted in a UV disinfection system such as that disclosed in provisional application serial No. 60/154,146. In this embodiment, a photodetector (1) is mounted on the outside of an enclosure (2) in which germicidal lamps are mounted. In this view, the electrical contact pins are shown projecting upward; the sensor is inside enclosure (2) and enclosure wall shown in FIG. 1(a). Germicidal lamps (not shown) are mounted in receptacles (3), projecting through enclosure (2) to the interior of a conduit (not shown) in which the fluid to be disinfected is flowing.

A shutter (5) is attached to solenoid (6). Actuation of the solenoid moves shutter (5) from a first position in which shutter (5) prevents UV radiation from impinging upon photodetector (1) to a second position in which UV light is not blocked.

In the preferred embodiment shown in FIG. 1, the shutter is rotatably mounted about an axially oriented shaft. Rotation of shutter (5) about shaft (9) is driven by horizontal movement of an arm attached to the solenoid. Rotation of the shutter exposes the photodetector to UV light emitted by the germicidal lamps. As shown in FIGS. 1(a) and 1(b), the portion of shutter (5) within enclosure (2) is moved away from a hole through which UV radiation passes to reach photodetector (1) by when solenoid (6) is actuated. As the solenoid is actuated, allowing UV radiation to impinge upon the photodetector, the electronic monitoring circuitry is enabled to enabled to capture a measurement.

The shutter is preferably made of sheet metal or plastic that is opaque to short wavelength UV. Other substances may be used, provided they are also opaque to short wavelength UV, and are not degraded by exposure to it.

In alternative embodiments different mechanisms for moving shutter (5) are used. For example, shutter (5) may be moved manually, without the use of solenoid (6). In yet other embodiments, different devices may be used to move shutter (5) from a position in which UV radiation is prevented from reaching photoreceptor. Stepping motors, electromagnets and other sources of mechanical power may be used to operate the shutter without departing from the scope of the present invention.

In yet other embodiments of the present invention, the photoreceptor itself can be moved from a first position, in which it is exposed to UV radiation to a second position in which it is not, without the need for a shutter. This can be accomplished by mounting the photoreceptor upon a rotatable member, that may be manually moved from a first to a second position, or may be moved by an external source of power, as previously described.

The sensor itself is preferably a photodiode that generates a current when irradiated with UV. Other electrical or electronic devices whose electrical properties change are also within the scope of the invention. For example light induced voltage or resistance may also be detected by use of the appropriate sensor.

The foregoing discussion and figures are for the purposes of illustrating the invention, and not to define its scope, which is defined by claims appended hereto.

We claim:

1. A device for selectively exposing a sensor to UV radiation in an HVAC system comprising:
(a) material that is opaque to UV radiation
(b) a mechanism for moving the material from a first position, wherein the material is interposed between a source of UV radiation and the sensor to a second position, wherein the material is not interposed between the source of UV and the sensor.

2. The device of claim 1 wherein the mechanism is an eletromechanical device for moving the material from the first position to the second position

3. The device of claim 1 wherein the mechanism is a solenoid

4. The device of claim 1 wherein the mechanism is an electric motor.

5. The device of claim 1 wherein the mechanism is a stepping motor.

6. The device of claim 1 wherein the mechanism is a spring.

7. A device for selectively exposing a sensor to UV radiation wherein a photodetector is moved from a first position, in which it is exposed to UV radiation, to a second position, where it is not exposed to UV radiation.

8. The device for selectively exposing a sensor to UV radiation of claim 7 wherein the photoreceptor is attached to a rotatable member, and rotation of the rotatable member moves the photodector from the first position to the second position.

9. The device for selectively exposing a sensor to UV radiation of claim 8 wherein rotation of the rotable member is produced by a solenoid.

10. The device for selectively exposition a sensor to UV radiation of claim 8, wherein rotation of the rotatable member is produced by an electric motor.

11. The device of claim 2, for secectively exposing a sensor to UV radiation wherein UV radiation is used to disinrect an HVAC system.

12. The device of claim 3 for selectively exposing a sensor to UV radiation wherein UV radiation is used to disinfect an HVAC system.

13. The device of claim 4 for selectively exposing a sensor to UV radiation wherein UV radiation is used to disinfect an HVAC system.

14. The device of claim 5 for selectively exposing a sensor to UV radiation wherein UV radiation is used to disinfect an HVAC system.

15. The device of claim 3 wherein the photodetector is a photodiode.
